(19) United States
(12) Patent Application Publication
(10) Pub. No.: US 2013/0003297 A1
(43) Pub. Date: Jan. 3, 2013

(54) Game Lock Box

(75) Inventors: Julie Quyen Du-Henson, Garland, TX (US); Kevin Martin Henson, Garland, TX (US)

(73) Assignee: Mrs. Julie Quyen Du-Henson, Garland, TX (US)

(21) Appl. No.: 13/171,447

(22) Filed: Jun. 29, 2011

(51) Int. Cl. H05K 7/20; H05K 7/00

(52) U.S. Cl. 361/695; 361/679.01

(57) ABSTRACT

This invention uses an innovative combination of existing technologies to achieve the novel result of managing access to some number of electronic devices that would normally not be suited to access control. Additionally the invention is specifically designed to enclose various configurations of power strips and surge protectors. One of the key features of this technology, is the property that devices can easily be added to or plugged into this device when it is open and unsecured. Once the lid is secured and closed, the attached devices cannot be unplugged. The design of the device ensures that there is ample room for cords to pass out of the device when the lid is secured, but not enough space to reach inside it with a tool and tamper with it.

This application acknowledges the numerous patents in the field methods of electronic power surge protection and contemplates no infringement. This application does not disclose any new method of protecting equipment from power surges, just managing access to devices that do perform that function. Numerous patents exist detailing various configurations of single and multi-outlet surge protectors. This technology is adaptable to service most if not all of them, and is not specific to any particular design of surge protector, rather, it is a device adapted to improve the function and security of and entire class of existing or new devices.

There are also numerous patents detailing lockable equipment racks, cabinets and enclosures for use in server rooms and industrial settings. These large specialized devices are normally fixed or semi fixed installations. This invention is targeted for entry level applications in the home/small business environment were it can be used to increase the usefulness of existing devices. This securable enclosure differs from other devices of its type in that it can be portable or fixed mounted. It is small and light enough to be easily portable, or hidden away behind the devices whose power it regulates.

### TECHNICAL FIELD OF THE INVENTION

This invention relates generally to the field of electronic security and specifically to the prevention of unauthorized use of electronic devices. This is accomplished by controlling access to the power switch of a surge protector or other multi outlet device. This ensures only authorized users can turn the switch ON. The invention further prevents unauthorized parties from disconnecting devices from the surge protector and plugging them into another location. This has apparent utility for safety, theft prevention, power conservation and parental control.

### BACKGROUND OF THE INVENTION

The original impetus for this invention is to allow parent to control the access children and adolescents have to electronics such as Televisions, Video players, computers and other entertainment devices. Many young people today arrive home before their parents do. They immediately turn on electronic entertainments, rather then getting their homework or studying done. While some cable boxes have timeout settings many other devices do not. This invention allows parents to have a way to disable a wide variety of electronics with a very inexpensive device.

This invention also has a number of safety and energy saving uses. There are a number of lock out devices that can be attached to individual cord to prevent them from being plugged in. This device performs a similar function on a group of devices. There is an optional feature that allows the enclosure to engage the power switch and move it to the OFF position upon closing and hold the switch under compression to ensure that when the enclosure is locked the power switch will always be in the OFF position.

### BRIEF DESCRIPTION OF THE DRAWINGS

FIG. 1A—OVERVIEW OF EXTERNAL HOUSING

This figure depicts the external configuration of the lock box. NOTE: NUMBER CONTIGUOUS BETWEEN FIGURES

FIG. 1B—SOURCE POWER CONNECTION END

This figure depicts details of the device where the main power cord passes through the upper lid and lower housing.

FIG. 1C—LOAD CONECTION END

This figure depicts details of the device where the attached devices power cords pass though the upper lid and lower housing.

FIG. 1D—CUTAWAY VIEW

This figure depicts the internal configuration of the lock box.

100 UPPER LID, when locked this portion of the device prevents access to the plugs, cords and the power switch contained within.

105 UPPER LID LATCH POINT, this portion of the device provides the physical and structural support for and external lock that can be of any suitable type, keyed, combination, etc.

110 LOWER LID LATCH POINT, this portion of the device provides the physical and structural support for and external lock that can be of any suitable type, keyed, combination, etc.

115 LOWER HOUSING, this comprises the main structure of the device; it has openings in it to facilitates its function.

120 POWER STRIP, the power strip portion of this device can be of any suitable design so long as it has a power switch and a means to plug several devices into it.

125 POWER SWITCH, this switch functions in the usual toggle fashion, to control the power distributed to attached devices.

130 SOURCE ACESS OPENING, this opening is of a specific shape to allow the plug for the power strip to pass through without allowing unauthorized parties to reach the switch.

135 LOAD ACESS OPENING, this opening is of a size and shape to allow multiple plugs and cords to attached to the power strip from the without allowing unauthorized parties the ability to reach the switch.

140 HINDGES. These allow the upper and lower portion of the device to move with respect to each other, so long as the lock is not engaged.

145 POWER OFF ASSURANCE TAB, this option feature is affixed to the upper lid in such a fashion that it ensures the switch is in the OFF position when the lid is closed.

150 UPPER LID RELIEF CUT, (LOAD), this portion of the device allows the power cords from several externally connected devices to exit device without interference.

155 UPPER LID RELIEF CUT, (SOURCE), this portion of the device allows the power cord from the power strip to exit device without interference.

160 UPPER LID HANDLE this portion of the device facilitates opening the lid or picking up the entire device. This feature can be considered optional.

165 SOURCE CORD, this is the power cord for the associated power strip.

165 LOAD POWER CORD(S), are attached to devices whose activation is to be controlled.

### DETAILED DESCRIPTION OF THE PREFERRED EMBODIMENTS AND BEST MODE

Note numbers assigned to components in figures carry over to subsequent figures, and duplicate explanations will not be given. The use of multiple views showing the same components is to enhance the understanding to the reader.

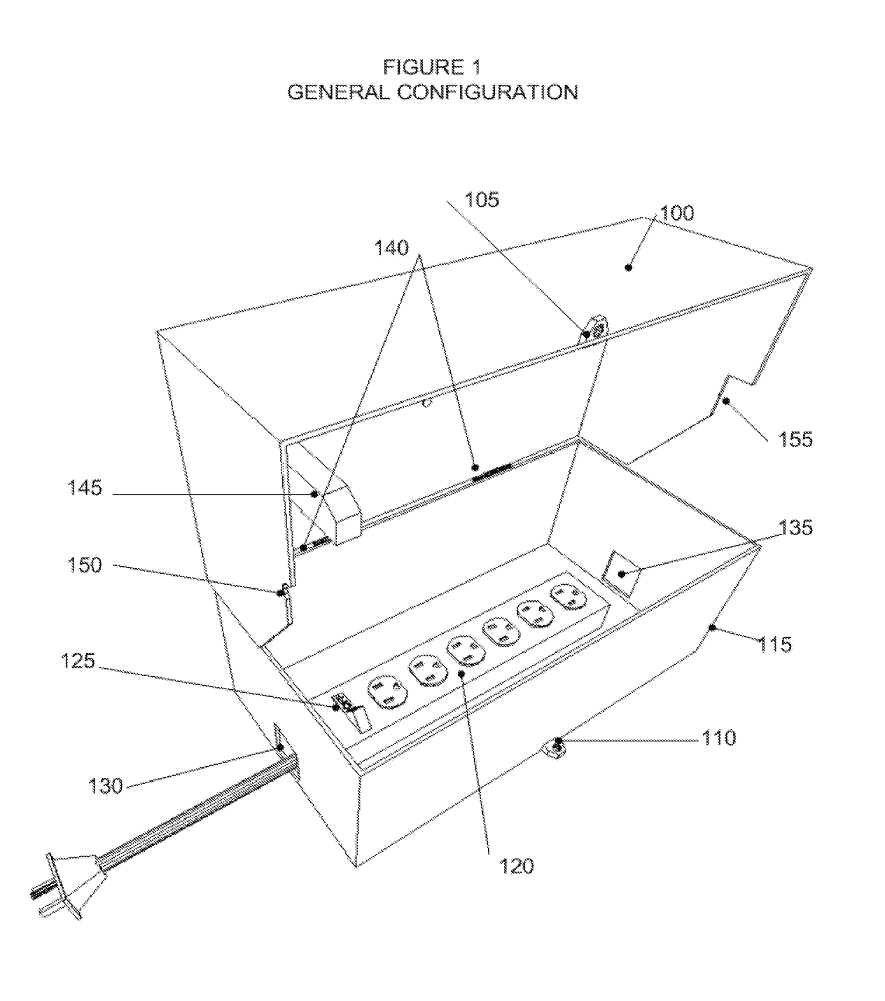

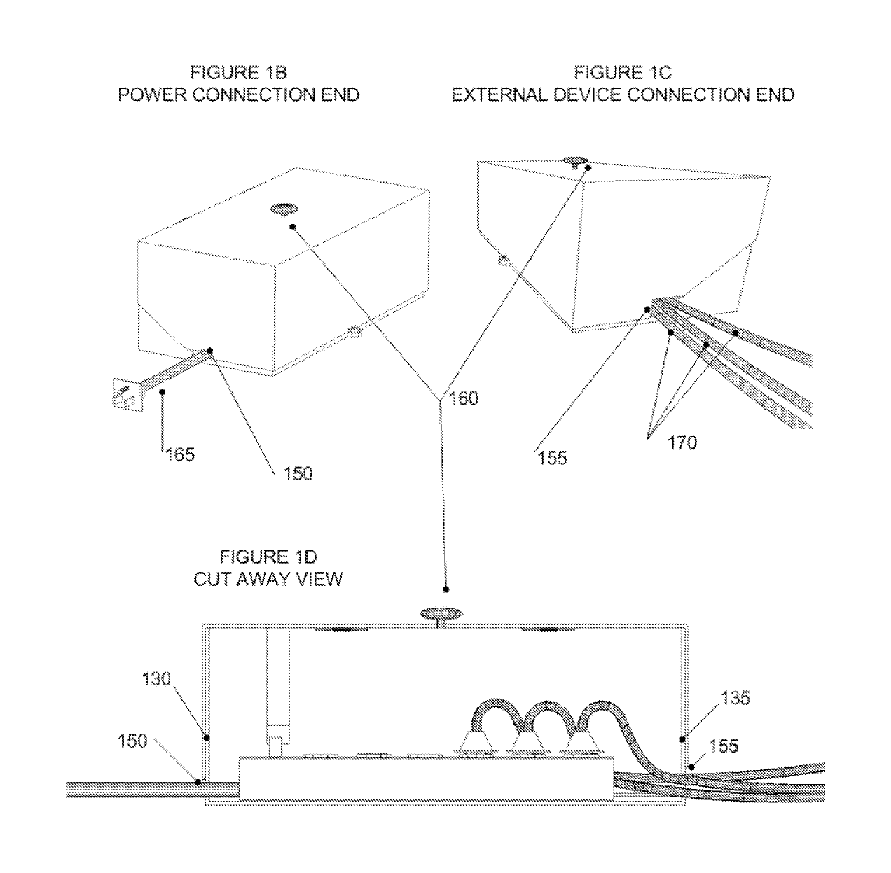

Referring to FIG. 1A, the device is adapted to surround a variety of surge protectors currently in use. While there are many lock out devices, and lockable housing for computer equipment, this device is unique in that it is adapted to service a wide variety of currently commercially available power conditional and surge protection equipment and enhance it so that attached device usage can be regulated.

The UPPER LID (100) is optimally constructed of a nonconductive and rigid material. Various plastics (ABS, thermo, thermo setting, etc.) may be highly desirable for this application. This portion of the device is movable due to the HINDGES (140), and facilitated by the HANDLE (160).

The POWER STRIP (surge protector, outlet expander, power conditioner) (120), may be an integral component or any suitable existing device that fits within the lower housing of the system. The POWER SWITCH may be of a any suitable type (toggle, button, slide or wireless remote). The power strip may be affixed to the lower housing either temporarily or permanently using any suitable fastener or adhesive, temporary, semi permanent or permanent.

Advanced variations of this device with integral power strips, could have programmable logic, memory and communication elements built into the power strip. This is also where overload, and temperature sensors would reside.

The LOWER ACCES OPENINGS are adapted to facilitate easy pass through and connections of the cords when the device is open. If the power strip is not an integral part of the device, the LOWER POWER OPENING (130) needs to be of sufficient size to allow the end of a grounded plug to pass unimpeded from the interior to the exterior. The LOWER LOAD ACCESS OPENING (135) needs to be of sufficient size to allow the ends of several grounded plugs and associate cords to pass unimpeded from the interior to the exterior. Once all the cords are plugged in the device may be closed, since the UPPER LID 100, fits over the LOWER HOUSING (115), the UPPER LID RELIEF CUTS (150, 155) effective shrink the size of the access openings. This is desirable since plugs should not be able to pass in and out of the device when it is secured. This also discourages the introduction of tampering tools from the outside. This is a key novel feature of this device that allows the easy movement of cords when it is open and prevents tampering when it is closed.

The POWER OFF ASSURACNE TAB (145) is an optional feature that may be employed to prevent the device from being secured around powered devices. This tab may be an integral part of the UPPER LID (100), or may be an adjustable/removable component that is attached to the UPPER LID in any suitable temporary or permanent fashion, including but not limited to (friction locks, tracks, tabs, slots, adhesives, hook and loop fasteners, penetrative fasteners, screws, or bolts). In the case of an integral power strip, the tab would not need to be repositionable. Furthermore, if the integral power strip had a remote switch, the ASSURACNE TAB would not be necessary.

Some form of locking mechanism is essential in order to secure the device. This can take the form of any suitable internal lock (key, combination, biometric, etc) or a simple EXTERNAL LATCH POINTS (105, 110). External latch points may be integral to the structure of the lid and housing or permanently affixed during manufacturing. These latch points give the device the flexibility to use a wide variety of currently available external locks.

In addition to safety and security, this system can provide to existing multi power devices, other features may be added. A model with integral surge protector, may have integrated audio device to be connected to external errors. Larger units may incorporate speakers, subwoofers and lockable volume controls. Integrated units may also be adapted to allow users to control at what times and for what duration devices can be used. Advanced versions of this device may have internally or externally programmable logic elements so that different sockets may have different access criteria, or parameters.

The inventors of this technology see a wide variety of domestic, commercial, industrial, and educational applications for this device. First of all this system allows parents to limit access to audio/visual equipment, computers, and video games even when they are not around. This will empower parent to curb after school recreation until homework and studies are complete.

This system also makes an effective security deterrent to theft of equipment. If it cannot be unplugged it is very hard to steal. Businesses may wish to use this technology in order to prevent unauthorized, after hours use of company resources. Integral load detection, temperature sensors and other measuring equipment may be added so that the device could shut off one or all attached devices if an unsafe condition were detected. Optionally, the device may be fitted with a fan and suitable air vents adapted to prevent over heating.

In industrial and medical environments this system may be employed to prevent people from unplugging vital equipment or activating hazardous devices.

This system may also be used to realize energy savings by powering down devices manually or at certain times so as to reduce the “standby” energy load of many electronic devices especially amplifiers and tuning circuits common in audio/visual and entertainment equipment.

The possible benefits of a low cost system adaptable to manage the power usage of electronic devices are limited sole by the imagination of the user.

What is claimed is:

1. A System for restricting access to one or more power plugs, within an enclosure or housing that can be secured, the system consisting a housing or container hinged into two movable portions, an attachment point for a lock, or integral lock, adapted to prevent unauthorized access to the interior space and area to attach the power strip or surge protector, and openings for both source and load power cords so they may be plugged in.

2. The System of claim 1 wherein the enclosure has openings to allow power cords to be connected to their respective devices, even when the box is closed.

3. The System of claim 2 wherein, when the enclosure is closed and secured that the power switch controlling one or more outlets and attached devices cannot be accessed, until the box is opened again.

4. The System of claim 3 wherein, when the enclosure is closed and secured that the power switch controlling one or more outlets and attached devises is automatically placed in the OFF position.

5. The System of claim 3 wherein, the power strip, or surge protector has a wireless remote for turning it ON and OFF.

6. The System of claim 2 wherein, when the enclosure is closed and secured a small fan and one or more air vents ensure that no devices overheat.

7. The System of claim 6 wherein, a small thermal sensors is used to measure internal temperature, and automatically turn the power OFF if and unsafe temperature is reached.

8. The System of claim 3 wherein, the device is connected to an IP connection either wireless or wired enabling remote access to the device and remote power management of anything connected to it.

9. A System for restricting access to one or more power plugs, within an enclosure that can be secured, the system consisting of a lower housing and an upper lid that are joined at a hinge, an attachment point for a lock, (or integral lock), and area to attach the power strip or surge protector, and opening for the power strip cord so it may be plugged in, the system further consist of upper and lower sections adapted to facilitate plugging, and unplugging cords in while the system is open and impairing access to cords when it is closed. This is accomplished by the interplay of lower housing access openings and upper lid relief cuts.

10. A System of claim 9 wherein the enclosure has openings to allow power cords to be connected to their respective devices, even when the box is closed.

11. The System of claim 10 wherein, when the enclosure is closed and secured that the power switch controlling one or more outlets and attached devices cannot be accessed, until the box is opened again.

12. The System of claim 11 wherein, when the device is closed and secured, the switch may not be turned on.

13. The System of claim 12 wherein, provisions are made for optional equipment to be attached on the inside of the device such as audio speakers.

14. The System of claim 12 wherein, provisions are made for managing the time, or duration the system may be used, either internally or externally.

15. The System of claim 14 wherein, programmable logic used to allow different sockets on the same device to have different access and operational criteria or parameters.

16. The System of claim 14 wherein, the operational parameter of the device may be programmed remotely by some suitable wireless means.

17. The System of claim 1 wherein, the system is equipped with a fan and a suitable air vent.

18. The System of claim 9 wherein, the system is equipped with a fan and a suitable air vent.

19. The System of claim 12 wherein, the system is equipped with a fan and a suitable air vent.
